(19) United States
(12) Patent Application Publication
(10) Pub. No.: US 2025/0248012 A1
(43) Pub. Date: Jul. 31, 2025

(54) HEAT MANAGEMENT FOR HEAD-MOUNTABLE DEVICE

(71) Applicant: Apple Inc., Cupertino, CA (US)

(72) Inventors: Anna V. MIRABELLA, San Francisco, CA (US); Jan K. QUIJALVO, San Jose, CA (US); Laura M. CAMPO, Santa Clara, CA (US); Sivesh SELVAKUMAR, Mountain View, CA (US)

(21) Appl. No.: 18/855,906

(22) PCT Filed: Apr. 17, 2023
(86) PCT No.: PCT/US2023/018861

§ 371 Date: Oct. 10, 2024

Related U.S. Application Data
(60) Provisional application No. 63/332,640, filed on Apr. 19, 2022.

(51) Int. Cl. H05K 7/20; G06F 1/16

(52) U.S. Cl. CPC H05K 7/20963; G06F 1/163; H05K 7/20154

(57) ABSTRACT

A head-mountable device can provide a thermal mitigation system that effectively manages heat while also allowing adjustment of optical modules to accommodate particular users. For a given interpupillary distance to accommodate a user, different heat sinks can be provided with optimized fin patterns, lengths, or shapes. Other mechanisms for managing airflow, such as intake modules, can be provided with custom or adjustable characteristics to achieve different airflow patterns and thereby accommodate movement of the optical modules. Such customization and/or adjustability of thermal mitigations by can allow users to experience optimal performance from temperature-sensitive modules such as displays, cameras, sensors, circuitry, and the like.

### CROSS REFERENCE TO RELATED APPLICATIONS

This application claims the benefit of priority to U.S. Provisional Patent Application No. 63/332,640, entitled, “HEAT MANAGEMENT FOR HEAD-MOUNTABLE DEVICE”, filed on Apr. 19, 2022, the disclosure of which is hereby incorporated herein in its entirety.

### TECHNICAL FIELD

The present description relates generally to head-mountable devices, and, more particularly, to fans and heat sinks to cool optical modules for head-mountable devices.

### BACKGROUND

A head-mountable device can be worn by a user to display visual information within the field of view of the user. The head-mountable device can be used as a virtual reality (VR) system, an augmented reality (AR) system, and/or a mixed reality (MR) system. A user may observe outputs provided by the head-mountable device, such as visual information provided on a display. The display can optionally allow a user to observe an environment outside of the head-mountable device. Other outputs provided by the head-mountable device can include speaker output and/or haptic feedback. A user may further interact with the head-mountable device by providing inputs for processing by one or more components of the head-mountable device. For example, the user can provide tactile inputs, voice commands, and other inputs while the device is mounted to the user's head.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates a side view of a head-mountable device, according to some embodiments of the present disclosure.

FIG. 2 illustrates a side view of a portion of a head-mountable device, according to some embodiments of the present disclosure.

FIG. 3 illustrates a front view of a portion of a head-mountable device with first heat sinks in a first configuration, according to some embodiments of the present disclosure.

FIG. 4 illustrates a front view of a portion of the head-mountable device of FIG. 3 with second heat sinks in a second configuration, according to some embodiments of the present disclosure.

FIG. 5 illustrates a front view of a portion of a head-mountable device with first heat sinks in a first configuration, according to some embodiments of the present disclosure.

FIG. 6 illustrates a front view of a portion of the head-mountable device of FIG. 5 with second heat sinks in a second configuration, according to some embodiments of the present disclosure.

FIG. 7 illustrates a modular heat sink, according to some embodiments of the present disclosure.

FIG. 8 illustrates a modular heat sink, according to some embodiments of the present disclosure.

FIG. 9 illustrates a modular heat sink, according to some embodiments of the present disclosure.

FIG. 10 illustrates a front view of a portion of a head-mountable device with first intake modules in a first configuration, according to some embodiments of the present disclosure.

FIG. 11 illustrates a front view of a portion of the head-mountable device of FIG. 10 without any intake modules, according to some embodiments of the present disclosure.

FIG. 12 illustrates a front view of a portion of the head-mountable device of FIG. 11 with second intake modules in a second configuration, according to some embodiments of the present disclosure.

FIG. 13 illustrates a front view of a portion of a head-mountable device with intake modules in a first configuration, according to some embodiments of the present disclosure.

FIG. 14 illustrates a front view of a portion of the head-mountable device of FIG. 12 with the intake modules in a second configuration, according to some embodiments of the present disclosure.

FIG. 15 illustrates a block diagram of a head-mountable device, in accordance with some embodiments of the present disclosure.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

Head-mountable devices, such as head-mountable displays, headsets, visors, smartglasses, head-up display, etc., can perform a range of functions that are managed by the components (e.g., sensors, circuitry, and other hardware) included with the wearable device. The head-mountable device can provide a user experience that is immersive or otherwise natural so the user can easily focus on enjoying the experience without being distracted by the mechanisms of the head-mountable device.

Components of a head-mountable device can generate heat during operation. Excessive heat for long durations of time can damage the components of the head-mountable device and cause discomfort to the user. Heat can be mitigated in a number of ways, including with active mechanisms (e.g., fans) that are integrated into the head-mountable device.

Head-mountable devices can also adjust the position of optical modules that contain displays for visual output to a user. The optical modules can be adjusted to properly align the optical axes thereof with the user's eyes. Based on such adjustments, the thermal solution to optimize heat mitigation within the optical modules can vary. For example, a different position of the optical module can alter the ideal flow path for air to pass by heat sinks of the optical modules.

Systems of the present disclosure can provide a thermal mitigation system that effectively manages heat while also allowing adjustment of optical modules to accommodate particular users. For a given interpupillary distance (IPD) to accommodate a user, different heat sinks can be provided with optimized fin patterns, lengths, or shapes. Other mechanisms for managing airflow, such as intake modules, can be provided with custom or adjustable characteristics to achieve different airflow patterns and thereby accommodate movement of the optical modules. Such customization and/or adjustability of thermal mitigations by can allow users to experience optimal performance from temperature-sensitive modules such as displays, cameras, sensors, circuitry, and the like. This can decrease the risk of sensor misalignment with CTE drift, minimize burn-in on displays, and improve overall long-term reliability. Customizing these components by IPD could also mitigate risks of system interferences in drop that may occur at specific IPD positions.

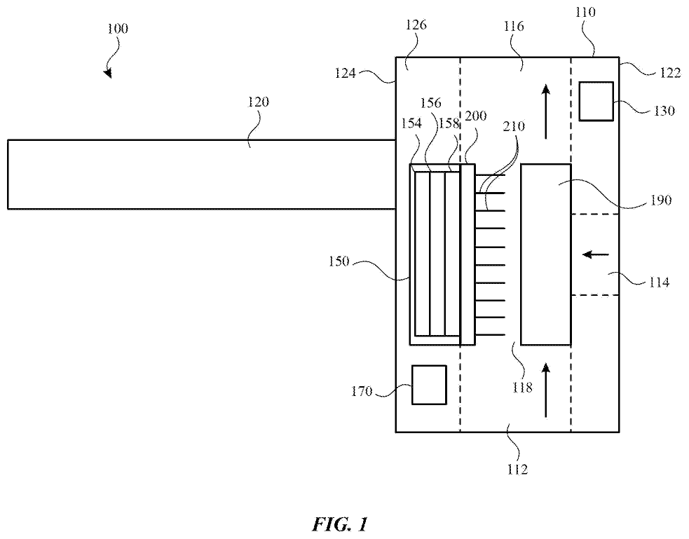

These and other embodiments are discussed below with reference to FIGS. 1-14. However, those skilled in the art will readily appreciate that the detailed description given herein with respect to these Figures is for explanatory purposes only and should not be construed as limiting.

According to some embodiments, for example as shown in FIG. 1, a head-mountable device 100 includes a frame 110 that is worn on a head of a user. The frame 110 can be positioned in front of the eyes of a user to provide information within a field of view of the user. The frame 110 can provide nose pads or another feature to rest on a user's nose. The frame 110 can be supported on a user's head with the securement element 120. The securement element 120 can wrap or extend along opposing sides of a user's head. The securement element 120 can include earpieces for wrapping around or otherwise engaging or resting on a user's ears. It will be appreciated that other configurations can be applied for securing the head-mountable device 100 to a user's head. For example, one or more bands, straps, belts, caps, hats, or other components can be used in addition to or in place of the illustrated components of the head-mountable device 100. By further example, the securement element 120 can include multiple components to engage a user's head.

The frame 110 can provide structure around a peripheral region thereof to support any internal components of the frame 110 in their assembled position. For example, the frame 110 can enclose and support various internal components (including for example integrated circuit chips, processors, memory devices and other circuitry) to provide computing and functional operations for the head-mountable device 100, as discussed further herein. Any number of components can be included within and/or on the frame 110 and/or the securement element 120.

The frame 110 can include and/or support one or more cameras 130. The cameras 130 can be positioned on or near an outer side of the frame 110 to capture images of views external to the head-mountable device 100. The captured images can be used for display to the user or stored for any other purpose.

The head-mountable device can be provided with display modules that provide visual output for viewing by a user wearing the head-mountable device. As further shown in FIG. 1, one or more optical modules 150 can be positioned on an inner side 124 of the head-mountable device 100, for example within an eye chamber 126. For example, a pair of optical modules 150 can be provided, where each optical module 150 is movably positioned to be within the field of view of each of a user's two eyes. Each optical module 150 can be adjusted to align with a corresponding eye of the user. For example, each optical module 150 can be moved along one or more axes until a center of each optical module 150 is aligned with a center of the corresponding eye.

The optical module 150 can include a display 156 for displaying visual information for a user. The display 156 can provide visual (e.g., image or video) output. The display 156 can be or include an opaque, transparent, and/or translucent display. The display 156 may have a transparent or translucent medium through which light representative of images is directed to a user's eyes. The display 156 may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface. The head-mountable device 100 can include a configured to help optically adjust and correctly project the image-based content being displayed by the display 156 for close viewing. The optical module 150 can include one or more lenses 154, mirrors, or other optical devices.

Additionally or alternatively, an optical module 150 can transmit light from a physical environment (e.g., as captured by a camera) for viewing by the user. Such an optical module 150 can include optical properties, such as lenses 154 for vision correction based on incoming light from the physical environment. Additionally or alternatively, an optical module 150 can provide information as a display within a field of view of the user. Such information can be provided to the exclusion of a view of a physical environment or in addition to (e.g., overlaid with) a physical environment.

A physical environment refers to a physical world that people can sense and/or interact with without aid of electronic systems. Physical environments, such as a physical park, include physical articles, such as physical trees, physical buildings, and physical people. People can directly sense and/or interact with the physical environment, such as through sight, touch, hearing, taste, and smell.

In contrast, a computer-generated reality (CGR) environment refers to a wholly or partially simulated environment that people sense and/or interact with via an electronic system. In CGR, a subset of a person's physical motions, or representations thereof, are tracked, and, in response, one or more characteristics of one or more virtual objects simulated in the CGR environment are adjusted in a manner that comports with at least one law of physics. For example, a CGR system may detect a person's head turning and, in response, adjust graphical content and an acoustic field presented to the person in a manner similar to how such views and sounds would change in a physical environment. In some situations, (e.g., for accessibility reasons), adjustments to characteristic(s) of virtual object(s) in a CGR environment may be made in response to representations of physical motions (e.g., vocal commands).

A person may sense and/or interact with a CGR object using any one of their senses, including sight, sound, touch, taste, and smell. For example, a person may sense and/or interact with audio objects that create 3D or spatial audio environment that provides the perception of point audio sources in 3D space. In another example, audio objects may enable audio transparency, which selectively incorporates ambient sounds from the physical environment with or without computer-generated audio. In some CGR environments, a person may sense and/or interact only with audio objects.

Examples of CGR include virtual reality and mixed reality.

A virtual reality (VR) environment refers to a simulated environment that is designed to be based entirely on computer-generated sensory inputs for one or more senses. A VR environment comprises a plurality of virtual objects with which a person may sense and/or interact. For example, computer-generated imagery of trees, buildings, and avatars representing people are examples of virtual objects. A person may sense and/or interact with virtual objects in the VR environment through a simulation of the person's presence within the computer-generated environment, and/or through a simulation of a subset of the person's physical movements within the computer-generated environment.

In contrast to a VR environment, which is designed to be based entirely on computer-generated sensory inputs, a mixed reality (MR) environment refers to a simulated environment that is designed to incorporate sensory inputs from the physical environment, or a representation thereof, in addition to including computer-generated sensory inputs (e.g., virtual objects). On a virtuality continuum, a mixed reality environment is anywhere between, but not including, a wholly physical environment at one end and virtual reality environment at the other end.

In some MR environments, computer-generated sensory inputs may respond to changes in sensory inputs from the physical environment. Also, some electronic systems for presenting an MR environment may track location and/or orientation with respect to the physical environment to enable virtual objects to interact with real objects (that is, physical articles from the physical environment or representations thereof). For example, a system may account for movements so that a virtual tree appears stationery with respect to the physical ground.

Examples of mixed realities include augmented reality and augmented virtuality.

An augmented reality (AR) environment refers to a simulated environment in which one or more virtual objects are superimposed over a physical environment, or a representation thereof. For example, an electronic system for presenting an AR environment may have a transparent or translucent display through which a person may directly view the physical environment. The system may be configured to present virtual objects on the transparent or translucent display, so that a person, using the system, perceives the virtual objects superimposed over the physical environment. Alternatively, a system may have an opaque display and one or more imaging sensors that capture images or video of the physical environment, which are representations of the physical environment. The system composites the images or video with virtual objects, and presents the composition on the opaque display. A person, using the system, indirectly views the physical environment by way of the images or video of the physical environment, and perceives the virtual objects superimposed over the physical environment. As used herein, a video of the physical environment shown on an opaque display is called “pass-through video,” meaning a system uses one or more image sensor(s) to capture images of the physical environment, and uses those images in presenting the AR environment on the opaque display. Further alternatively, a system may have a projection system that projects virtual objects into the physical environment, for example, as a hologram or on a physical surface, so that a person, using the system, perceives the virtual objects superimposed over the physical environment.

An augmented reality environment also refers to a simulated environment in which a representation of a physical environment is transformed by computer-generated sensory information. For example, in providing pass-through video, a system may transform one or more sensor images to impose a select perspective (e.g., viewpoint) different than the perspective captured by the imaging sensors. As another example, a representation of a physical environment may be transformed by graphically modifying (e.g., enlarging) portions thereof, such that the modified portion may be representative but not photorealistic versions of the originally captured images. As a further example, a representation of a physical environment may be transformed by graphically eliminating or obfuscating portions thereof.

An augmented virtuality (AV) environment refers to a simulated environment in which a virtual or computer generated environment incorporates one or more sensory inputs from the physical environment. The sensory inputs may be representations of one or more characteristics of the physical environment. For example, an AV park may have virtual trees and virtual buildings, but people with faces photorealistically reproduced from images taken of physical people. As another example, a virtual object may adopt a shape or color of a physical article imaged by one or more imaging sensors. As a further example, a virtual object may adopt shadows consistent with the position of the sun in the physical environment.

There are many different types of electronic systems that enable a person to sense and/or interact with various CGR environments. Examples include head-mountable systems, projection-based systems, heads-up displays (HUDs), vehicle windshields having integrated display capability, windows having integrated display capability, displays formed as lenses designed to be placed on a person's eyes (e.g., similar to contact lenses), headphones/earphones, speaker arrays, input systems (e.g., wearable or handheld controllers with or without haptic feedback), smartphones, tablets, and desktop/laptop computers. A head-mountable system may have one or more speaker(s) and an integrated opaque display. Alternatively, a head-mountable system may be configured to accept an external opaque display (e.g., a smartphone). The head-mountable system may incorporate one or more imaging sensors to capture images or video of the physical environment, and/or one or more microphones to capture audio of the physical environment. Rather than an opaque display, a head-mountable system may have a transparent or translucent display. The transparent or translucent display may have a medium through which light representative of images is directed to a person's eyes. The display may utilize digital light projection, OLEDs, LEDs, uLEDs, liquid crystal on silicon, laser scanning light source, or any combination of these technologies. The medium may be an optical waveguide, a hologram medium, an optical combiner, an optical reflector, or any combination thereof. In one embodiment, the transparent or translucent display may be configured to become opaque selectively. Projection-based systems may employ retinal projection technology that projects graphical images onto a person's retina. Projection systems also may be configured to project virtual objects into the physical environment, for example, as a hologram or on a physical surface.

Referring again to FIG. 1, the head-mountable device can be provided with one or more flow channels that extend through at least a portion of the frame thereof to provide cooling to components of the head-mountable device. As shown in FIG. 1, the flow channels can include and/or be connected to a side inlet 112 and/or a front inlet 114. The side inlet 112 can provide airflow directly to one or more components of the optical module 150, such as a circuit component 158. The side inlet 112 and/or the front inlet 114 can provide airflow directly to fan 190 and/or to a heat sink 200 coupled to the optical module 150 of the head-mountable device 100. Additionally or alternatively, the fan 190 can push air against or draw air across the heat sink 200 and to an outlet 116 and/or other outlets for exhaust out of the head-mountable device 100.

The fan 190 can direct air or another gas within, against, or across one or more components of the optical module 150, such as the heat sink 200. The fan 190 can be operated based on one or more operating parameters that are controllable during use. The operating parameters can be determined, at least in part, based on a demand for cooling (e.g., based on a temperature of one or more components). The operating parameters can be further determined based on acceptable sound levels and characteristics to be produced by the fan 190 and along the flow channel.

While the side inlet 112 is depicted at a bottom portion of the frame 110, the front inlet 114 is depicted at a front portion of the frame 110, and the outlet 116 is depicted at a top portion of the frame 110, it will be recognized that inlets, outlets, and flow channels there between can be positioned at any portion of the head-mountable device 100. The outlet 116 can be provided at a location that will allow exiting air to exhaust to an environment that is not disruptive to the user. For example, the outlet 116 can be provided at a location and in and orientation that directs hot air away from the user. Multiple flow channels can be interconnected, such that multiple inlets and/or multiple outlets are connected to each other.

One or more heat sinks 200 can be operated to provide cooling to one or more circuit components 158 of the optical module 150. The circuit component 158 can be an electrical component that generates heat during operation. The circuit component 158 can be a component of a circuit board. The circuit component 158 can be operably and structurally coupled to other components of the optical module 150. A portion of the heat sink 200 can be thermally connected to the circuit component 158.

The fan, a heat sink, and/or an intake module can be positioned at or connected to a side inlet 112, a front inlet 114, an outlet 116, or a position between two or more of the foregoing. For example, the fan 190 and/or the optical module 150 can be positioned within a component chamber 118 of the head-mountable device 100.

While several components are shown within the frame 110, it will be understood that some or all of these components can be located anywhere within or on the head-mountable device 100. For example, one or more of these components can be positioned within the securement element of the head-mountable device 100.

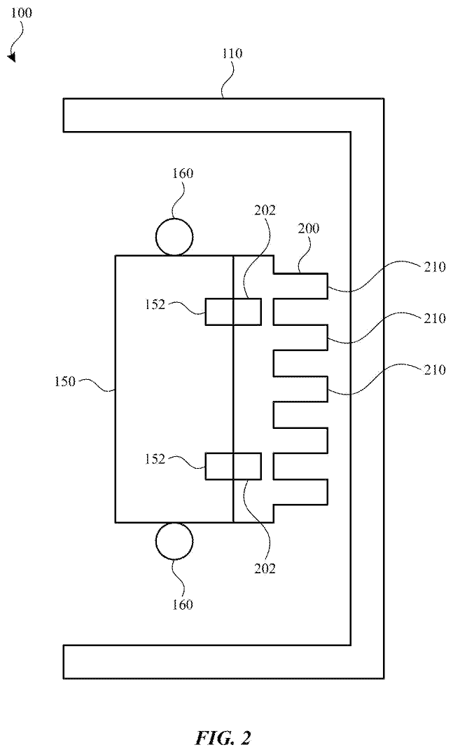

Referring now to FIG. 2, the heat sink 200 can be thermally connected to components to be cooled. The heat sink 200 can provide one or more fins 210. The heat sink 200 can be thermally connected to the optical module 150 and/or component thereof. The heat sink 200 can be thermally connected to the optical module 150 by a direct connection (e.g., no intervening structure) or by a thermal interface. For example, a thermal paste or other thermally conduct of material can be provided to thermally and/or structurally connect the optical module 150 to the heat sink 200. Heat emanating from the optical module 150 is received by the heat sink 200 and directed to the fins 210.

According to some embodiments, the heat sink 200 can provide an integrated structure that is formed of a unitary and continuous material. The heat sink 200, including the fins 210, can be a monolithic structure, rather than an assembly of parts. As used herein, a monolithic structure is one that is integrally formed of a single piece of material, rather than of separate pieces that are joined together by an interface. For example, the heat sink 200, including the fins 210, can be a unibody and/or unitary structure. By providing a monolithic, unitary, and/or unibody heat sink 200, the heat sink 200 does not contain interfaces or discontinuities, such as those that occur in assembled parts. Accordingly, the monolithic, unitary, and/or unibody heat sink 200 can be fabricated to more precise and consistent dimensions as well as provide greater structural support and thermal conductivity.

The heat sink 200, including the fins 210, can be of a metal or other material having high thermal conductivity. The material can provide high rigidity and strength to provide support to components mounted to the heat sink 200 and to securely mount to other components (e.g., the frame) of the head-mountable device.

Referring again to FIG. 2, systems of the present disclosure provide a head-mountable device with exchangeable heat sinks that provide different heat mitigation characteristics to achieve the results that are desired by a user. For example, a head-mountable device 10 can be provided with a heat sink 200 that can be detached from the optical module 150. Optical module engagers 152 of the optical module 150 can interact with heat sink engagers 202 of the heat sink 200 to provide a secure and reversible coupling. The modular configurations allow a user to easily customize one or more optical modules with one or more heat sinks to provide cooling thereto. The optical modules 150 and/or the heat sinks 200 can be easily exchanged with each other to provide different cooling features at different times.

As used herein, “modular” or “module” can refer to a characteristic that allows an item, such as a heat sink or other module, to be connected, installed, removed, swapped, and/or exchanged by a user in conjunction with another item, such as an optical module of a head-mountable device. Connection of a heat sink with an optical module can be performed and reversed, followed by disconnection and connection of another heat sink with the same optical module or another optical module with the same heat sink. As such, multiple heat sinks can be exchangeable with each other with respect to a given optical module. Further, multiple optical modules can be exchangeable with each other with respect to a given heat sink.

A heat sink can be connected to an optical module in a manner that allows the heat sink to be removed thereafter. The connection can be fully reversible, such that when the heat sink and the optical module are disconnected, each is restored to a condition held prior to the connection. The connection can be fully repeatable, such that after the heat sink and the optical module are disconnected, the same or a different optical module and heat sink pair can be connected in the same way. The heat sink and optical module can be securely and temporarily connected, rather than permanently, fixedly, or resiliently connected (e.g., via chemical and/or molecular bond). For example, connection and disconnection of the heat sink and optical module are facilitated in a manner that does not cause permanent damage, harm, or deformation to the heat sink or the optical module. A heat sink and an optical module can be connected in a manner that secures the relative positions of the heat sink and the optical module with respect to each other.

As further shown in FIG. 2, engagers can facilitate coupling of the heat sink 200 to the optical module 150 in a relative position and orientation. The optical module 150 and the heat sink 200 can be securely and releasably coupled together. For example, optical module engagers 152 can releasably engage heat sink engagers 202. One or more of various mechanisms can be provided to secure the components to each other. For example, mechanisms such as locks, latches, snaps, slides, channels, screws, clasps, threads, magnets, pins, an interference (e.g., friction) fit, knurl presses, bayoneting, fused materials, weaves, knits, braids, and/or combinations thereof can be included to couple and/or secure the heat sink 200 and the optical module 150 together. Optionally, the components can remain secured to each other until an optional release mechanism is actuated. The release mechanism can be provided for access by a user.

The optical modules 150 can be mounted to the frame 110 via slidable guide rods 160, tracks, or other structures that permit manual or electronically actuated movement of one or more of the optical modules 150 to adjust the distance there between. The optical modules 150 can each include one or more hangers that interact with guide rods of the head-mountable device 100 to facilitate movement. One or more motors can be operated to effect movement of the optical module 150 with respect to the frame 110. The motors can operate independently to move each of the optical modules 150. Additionally or alternatively, a single motor can be operated to simultaneously move each of the optical modules 150, for example with opposite but symmetrical movement. Movement (e.g., adjustments to position and/or orientation) of the optical module 150 results in corresponding movement of the display thereof.

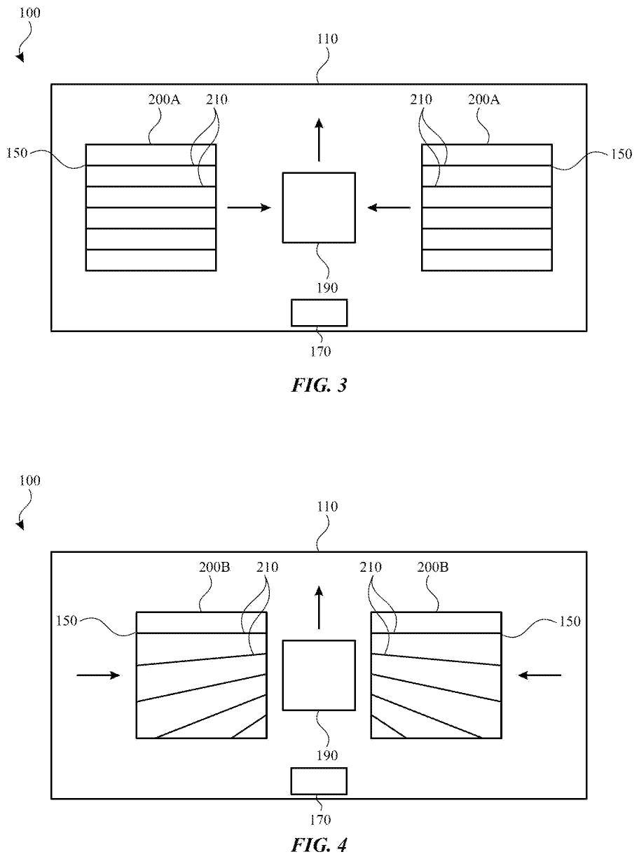

Referring now to FIGS. 3 and 4, the optical modules of the head-mountable device can be adjustable to accommodate the facial features of the user wearing the head-mountable device and align each optical module with a corresponding eye of the user.

As shown in FIG. 3, the head-mountable device 10 can include one or more sensors 170. The sensor 170 can be positioned and arranged to detect a characteristic of the user, such as facial features. For example, such a user sensor can perform facial feature detection, facial movement detection, facial recognition, eye tracking, user mood detection, user emotion detection, voice detection, and the like. While only one sensor 170 is depicted in FIG. 3, it will be understood that any number of sensors 170 can be provided. For example, a sensor 170 can be coupled to, included with, or part of an optical module 150. Accordingly, such a sensor 170 can move with the optical module 150 and be operated to detect the presence or absence of an eye (e.g., pupil, etc.) of a user, as well as the position and/or orientation thereof with respect to the head-mountable device 100. Such detections can further be used to determine whether the display of the optical module is in an optimal position and/or orientation with respect to the eye of the user and/or whether adjustments to the optical module 150 would be appropriate.

Each optical module 150 can be adjusted to align with a corresponding eye of the user. For example, each optical module 150 can be moved along and/or about one or more axes until a center of each optical module 150 is aligned with a center of the corresponding eye. Accordingly, the distance between the optical modules 150 can be set based on an interpupillary distance (“IPD”) of the user. IPD is defined as the distance between the centers of the pupils of a user's eyes. While translational movement is depicted in FIGS. 3 and 4, it will be further understood that rotational movement can, additionally or alternatively, be facilitated with respect to the frame 110.

The pair of optical modules 150 can be mounted to the frame 110 and separated by a distance. The distance between the pair of optical modules 150 can be designed to correspond to the IPD of a user. The distance can be adjustable to account for different IPDs of different users that may wear the head-mountable device 10. For example, either or both of the optical modules 150 may be movably mounted to the frame 110 to permit the optical modules 150 to move or translate laterally to make the distance larger or smaller. Any type of manual or automatic mechanism may be used to permit the distance between the optical modules 150 to be an adjustable distance.

Additionally or alternatively, the optical modules 150 can each be moved to a target location based on a desired visual effect that corresponds to user's perception of the optical module 150 when it is positioned at the target location. The target location can be determined based on a focal length of the user and/or optical elements of the system. For example, the user's eye and/or optical elements of the system can determine how the visual output of the optical module 150 will be perceived by the user. The distance between the optical module 150 and the user's eye and/or the distance between the optical module 150 and one or more optical elements can be altered to place the optical module 150 at, within, or outside of a corresponding focal distance. Such adjustments can be useful to accommodate a particular user's eye, corrective lenses, and/or a desired optical effect.

As further shown in FIGS. 3 and 4, as the optical modules move to accommodate the eyes of the user, the flow dynamics of air across the heat sinks can be altered. For example, the distance between the heat sinks and the fan 190 can be adjusted. As such, the types of fins 210 needed to optimize airflow can change depending on the position of the optical modules and/or the heat sinks. Accordingly, the heat sinks can be exchanged to accommodate different positions of the optical modules 150.

As shown in FIG. 3, a first heat sink 200A can be provided to each of the optical modules 150 while the optical modules 150 are in a first configuration (e.g., at a first distance away from the fan 190 or other position with respect to the frame 110) of the head-mountable device 100. As shown in FIG. 4, a second heat sink 200B can be provided to each of the optical modules 150 while the optical modules 150 are in a second configuration (e.g., at a second distance away from the fan 190 or other position with respect to the frame 110) of the head-mountable device 100. It will be understood that the first distance and the second distance of the optical modules 150 with respect to the fan 190 can be different (e.g., greater or less). Accordingly, the pathway from the fins 210 to the fan 190 can be different depending on the position of the optical modules 150. The appropriate heat sink to be coupled to each of the optical modules 150 can be selected based on a direction in which the fins 210 extend. For example, the fins 210 can extend in a direction that is oriented toward the fan 190 while the heat sink is coupled to the corresponding optical module 150. The user or the system itself can exchange the heat sinks as needed for a given position of the optical modules 150. Additionally or alternatively, the head-mountable device 100 can prompt the user to exchange the heat sinks, including providing an indication of which heat sink as well as instructions for performing the exchange.

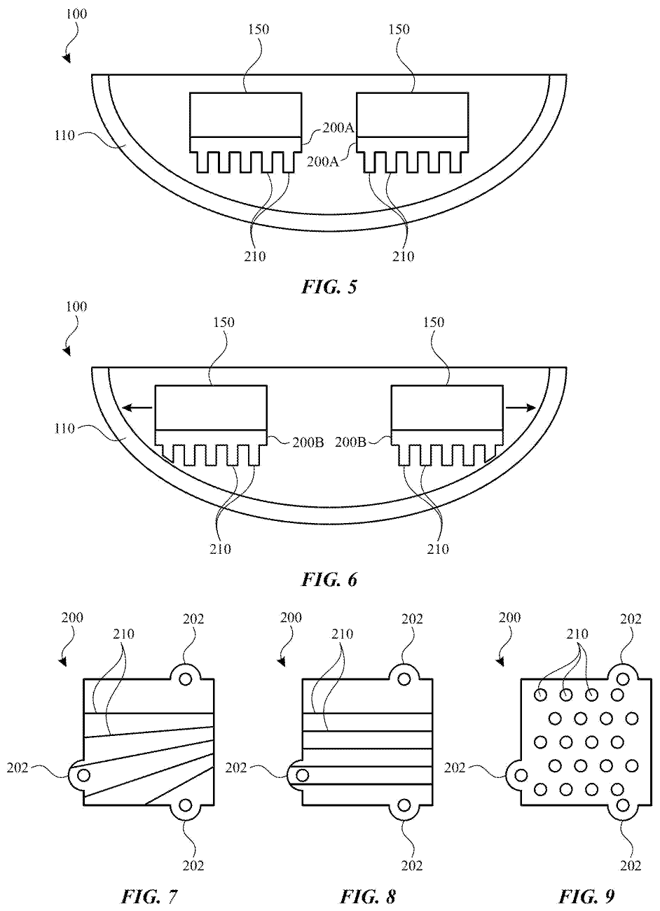

Referring now to FIGS. 5 and 6, the heat sinks can be selected to avoid interference with other components of the head-mountable device. As shown in FIGS. 5 and 6, as the optical modules 150 move to accommodate the eyes of the user, the position of the heat sinks can change with respect to other components of the head-mountable device 100, such as the frame 110. Accordingly, the heat sinks can be exchanged to accommodate their position without interfering (e.g., contacting) other components of the head-mountable device 100.

As shown in FIG. 5, a first heat sink 200A can be provided to each of the optical modules 150 while the optical modules 150 are in a first configuration (e.g., at a first distance away from the frame 110) of the head-mountable device 100. As shown in FIG. 6, a second heat sink 200B can be provided to each of the optical modules 150 while the optical modules 150 are in a second configuration (e.g., at a second distance away from the frame 110) of the head-mountable device 100. It will be understood that the first distance and the second distance of the optical modules 150 with respect to the frame 110 can be different (e.g., greater or less). Accordingly, the fins 210 of different heat sinks (e.g., 200A and 200B) can extend to different maximum heights (e.g., one being greater or less than the other). It will be understood that only some of the fins 210 need be different between any alternative pair of heat sinks. The appropriate heat sink to be coupled to each of the optical modules 150 can be selected based on heights of the fins 210 that can be accommodated while the heat sink is coupled to the corresponding optical module 150. Additionally or alternatively, the head-mountable device 100 can prompt the user to exchange the heat sinks, including providing an indication of which heat sink as well as instructions for performing the exchange.

Referring now to FIGS. 7-9, heat sinks can vary with respect to one or more of a variety of characteristics. For example, at least one of the size, shape, profile, dimension, aspect ratio, surface feature, texture, and the like can be different among multiple heat sinks 200 and/or the fins 210 thereof. For example, different heat sinks 200 can have fins 210 with different sizes and/or shapes to provide different flow characteristics and/or accommodate other components of a head-mountable device. As shown in FIGS. 7 and 8, fins 210 of any given heat sink 200 can extend to form an angle with respect to each other, and the fins 210 of another heat sink 200 can extend to form a different angle with respect to each other. Such angles can provide different entry and exit directions for air flow through the heat sink 200. Accordingly, heat sinks 200 can be configured to direct air to the fan as desired based on the position of the optical module to which the heat sink is coupled.

As shown in FIGS. 9, the fins 210 can form other shapes, such as posts, arms, and the like. The fins 210 can be arranged in multiple rows, columns, and the like with interruptions, spaces, and/or gaps therebetween. Such a configuration allows air to flow between and around multiple fins 210 through gaps therebetween. It will be understood that other shapes are contemplated. Additionally or alternatively, the fins 210 of any one heat sink 200 can vary in size, shape, composition (e.g., material), and the like.

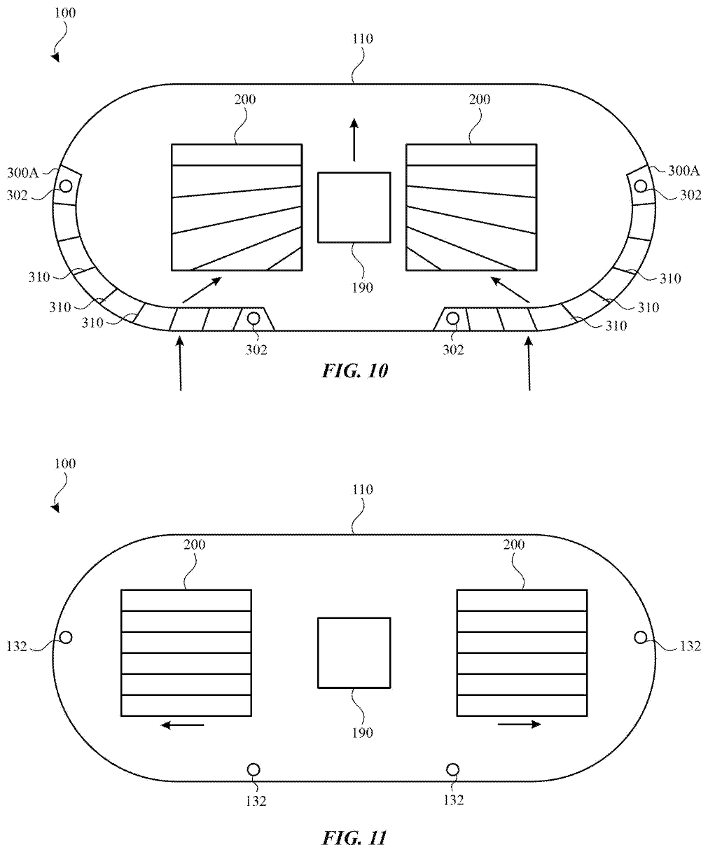

Referring now to FIGS. 10-12, intake modules can be exchanged to provide optimal air flow based on the position and/or arrangement of the optical modules and/or the heat sinks. As shown in FIGS. 10-12, as the optical modules move to accommodate the eyes of the user, the flow dynamics of air across the heat sinks can be altered, based at least in part on the selection of one or more of a variety of heat sinks 200. For example, the distance between the heat sinks 200 and the intake modules 300 can be adjusted. As such, the types of vanes 310 needed to optimize airflow can change depending on the position of the optical modules and/or the heat sinks 200. Accordingly, the intake modules 300 can be exchanged to accommodate different positions of the heat sinks 200.

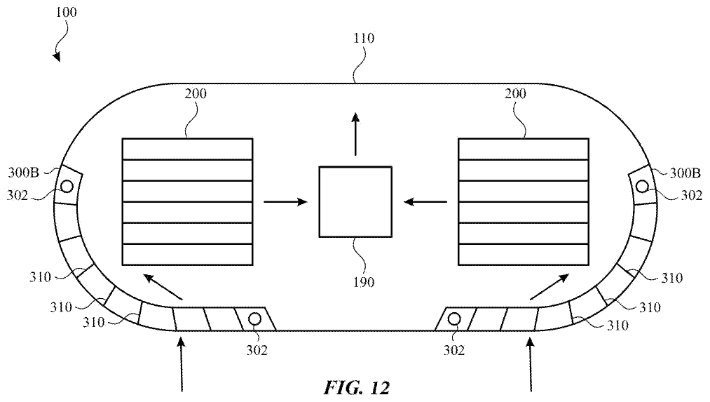

As shown in FIG. 10, one or more first intake modules 300A can be provided to the frame 110 while the optical modules and/or heat sinks 200 are in a first configuration (e.g., at a first distance away from the first intake modules 300A or other position with respect to the frame 110) of the head-mountable device 100. As shown in FIG. 11, one or more intake modules can be removed from the frame 110 by decoupling from the frame engagers 132, as described further herein. As shown in FIG. 12, a second intake module 300B can be provided to the frame 110 while the optical modules and/or heat sinks 200 are in a second configuration (e.g., at a second distance away from the frame 110 or other position with respect to the frame 110) of the head-mountable device 100. It will be understood that the first distance and the second distance of the optical modules 150 with respect to the frame 110 can be different (e.g., greater or less), and one or more of a variety of different heat sinks 200 can be selected. Accordingly, the pathway from the vanes 310 to the heat sinks 200 can be different depending on the position of the heat sinks 200. The appropriate intake module to be coupled to the frame 110 can be selected based on a direction in which the vanes 310 extend. For example, the vanes 310 can extend in a direction that is oriented toward the corresponding heat sink. The user or the system itself can exchange the intake modules as needed for a given position of the heat sinks 200. Additionally or alternatively, the head-mountable device 100 can prompt the user to exchange the intake modules, including providing an indication of which intake module as well as instructions for performing the exchange.

As further shown in FIGS. 10-12, engagers can facilitate coupling of the intake modules 300 to the frame 110 in a relative position and orientation. The intake modules 300 and the frame 110 can be securely and releasably coupled together. For example, frame engagers 132 of the frame 110 can releasably engage intake module engagers 302. One or more of various mechanisms can be provided to secure the components to each other. For example, mechanisms such as locks, latches, snaps, slides, channels, screws, clasps, threads, magnets, pins, an interference (e.g., friction) fit, knurl presses, bayoneting, fused materials, weaves, knits, braids, and/or combinations thereof can be included to couple and/or secure the intake modules 300 and the frame 110 together. Optionally, the components can remain secured to each other until an optional release mechanism is actuated. The release mechanism can be provided for access by a user.

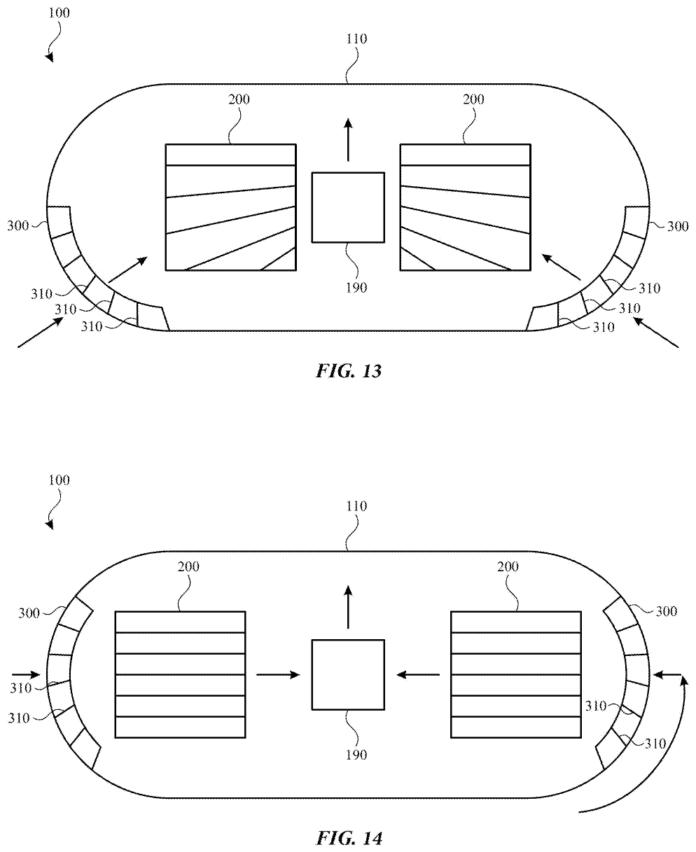

Referring now to FIGS. 13 and 14, intake modules can be moved to provide optimal air flow based on the position and/or arrangement of the optical modules and/or the heat sinks. As shown in FIGS. 13 and 14, as the optical modules move to accommodate the eyes of the user, the flow dynamics of air across the heat sinks can be altered, based at least in part on the selection of one or more of a variety of heat sinks 200. For example, the distance between the heat sinks 200 and the intake modules 300 can be adjusted. As such, the position and/or orientation of the vanes 310 can change to optimize airflow, thereby accommodating the position of the optical modules and/or the heat sinks 200. Accordingly, the intake modules 300 can be moved (e.g., by sliding) to accommodate different positions of the heat sinks 200.

As shown in FIG. 13, one or more intake modules 300 can be provided at a first position and/or orientation with respect to the frame 110 while the optical modules and/or heat sinks 200 are in a first configuration (e.g., at a first distance away from the intake modules 300 or other position with respect to the frame 110) of the head-mountable device 100. As shown in FIG. 14, the intake modules 300 can be moved (e.g., by sliding) along the frame 110 while the optical modules and/or heat sinks 200 are in a second configuration (e.g., at a second distance away from the intake modules 300 or other position with respect to the frame 110) of the head-mountable device 100. It will be understood that the first distance and the second distance of the optical modules 150 with respect to the frame 110 can be different (e.g., greater or less), and one or more of a variety of different heat sinks 200 can be selected. Accordingly, the pathway from the vanes 310 to the heat sinks 200 can be different depending on the position of the heat sinks 200 and the positions of the intake modules 300. The appropriate positions for the intake modules 300 with respect to the frame 110 can be selected based on a direction in which the vanes 310 to achieve the desired air flow. For example, the vanes 310 can extend in a direction that is oriented toward the corresponding heat sink 200. The user or the system itself can move (e.g., slide) the intake modules 300 as needed for a given position of the heat sinks 200. One or more motors can be operated to effect movement of the intake modules 300 with respect to the frame 110. To facilitate movement, such as sliding, one or more guides, tracks, rails, grooves, and the like can be provided for engagement between the frame 110 and the intake module(s). Additionally or alternatively, the head-mountable device 100 can prompt the user to manually move (e.g., slide) the intake modules 300, including providing instructions for performing the adjustment.

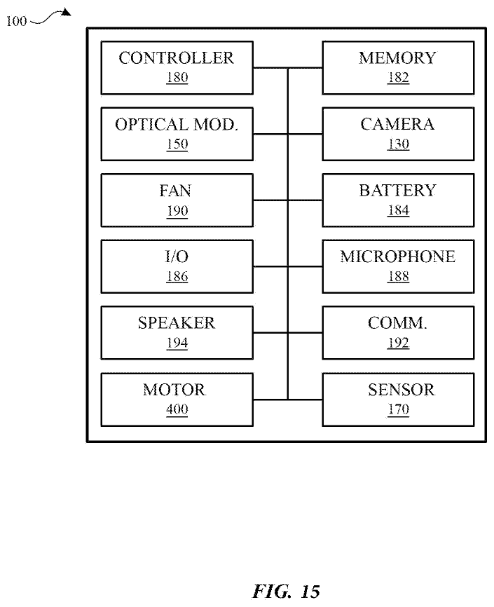

Referring now to FIG. 15, components of the head-mountable device can be operably connected to provide the performance described herein. FIG. 15 shows a simplified block diagram of an illustrative head-mountable device 100 in accordance with one embodiment of the invention. It will be appreciated that components described herein can be provided on either or both of a frame and/or a securement element of the head-mountable device 100. It will be understood that additional components, different components, or fewer components than those illustrated may be utilized within the scope of the subject disclosure.

As shown in FIG. 15, the head-mountable device 100 can include a controller 180 with one or more processing units that include or are configured to access a memory 182 having instructions stored thereon. The instructions or computer programs may be configured to perform one or more of the operations or functions described with respect to the head-mountable device 100. The controller 180 can be implemented as any electronic device capable of processing, receiving, or transmitting data or instructions. For example, the controller 180 may include one or more of: a microprocessor, a central processing unit (CPU), an application-specific integrated circuit (ASIC), a digital signal processor (DSP), or combinations of such devices. As described herein, the term “processor” is meant to encompass a single processor or processing unit, multiple processors, multiple processing units, or other suitably configured computing element or elements.

The memory 182 can store electronic data that can be used by the head-mountable device 100. For example, the memory 182 can store electrical data or content such as, for example, audio and video files, documents and applications, device settings and user preferences, timing and control signals or data for the various modules, data structures or databases, and so on. The memory 182 can be configured as any type of memory. By way of example only, the memory 182 can be implemented as random access memory, read-only memory, Flash memory, removable memory, or other types of storage elements, or combinations of such devices.

The head-mountable device 100 can include the fan 190 and/or any other suitable component for cooling down components of the head-mountable device 100. Suitable components can include, for example, fans, pipes for transferring heat, vents, apertures, holes, any other component suitable for distributing and diffusing heat, or any combination thereof. The fan 190 and/or other components, such as heat sinks, may also or instead be manufactured from materials selected for heat dissipation properties. For example, a housing of the head-mountable device 100 may be configured to distribute heat away from components thereof and/or the user.

The head-mountable device 100 can include a battery 184, which can charge and/or power components of the head-mountable device 100. The battery 184 can also charge and/or power components connected to the head-mountable device 100.

The head-mountable device 100 can include an input/output component 186, which can include any suitable component for connecting head-mountable device 100 to other devices. Suitable components can include, for example, audio/video jacks, data connectors, or any additional or alternative input/output components. The input/output component 186 can include buttons, keys, or another feature that can act as a keyboard for operation by the user.

The head-mountable device 100 can include the microphone 188 as described herein. The microphone 188 can be operably connected to the controller 180 for detection of sound levels and communication of detections for further processing, as described further herein.

The head-mountable device 100 can include the speakers 190 as described herein. The speakers 194 can be operably connected to the controller 180 for control of speaker output, including sound levels, as described further herein.

The head-mountable device 100 can include one or more other sensors. Such sensors can be configured to sense substantially any type of characteristic such as, but not limited to, images, pressure, light, touch, force, temperature, position, motion, and so on. For example, the sensor can be a photodetector, a temperature sensor, a light or optical sensor, an atmospheric pressure sensor, a humidity sensor, a magnet, a gyroscope, an accelerometer, a chemical sensor, an ozone sensor, a particulate count sensor, and so on. By further example, the sensor can be a bio-sensor for tracking biometric characteristics, such as health and activity metrics. Other user sensors can perform facial feature detection, facial movement detection, facial recognition, eye tracking, user mood detection, user emotion detection, voice detection, etc. Sensors can include a camera which can capture image-based content of the outside world.

The head-mountable device 100 can include communications circuitry 228 for communicating with one or more servers or other devices using any suitable communications protocol. For example, communications circuitry 228 can support Wi-Fi (e.g., a 802.11 protocol), Ethernet, Bluetooth, high frequency systems (e.g., 900 MHZ, 2.4 GHz, and 5.6 GHz communication systems), infrared, TCP/IP (e.g., any of the protocols used in each of the TCP/IP layers), HTTP, BitTorrent, FTP, RTP, RTSP, SSH, any other communications protocol, or any combination thereof. Communications circuitry 228 can also include an antenna for transmitting and receiving electromagnetic signals.

The head-mountable device 100 can include adjustment control components described herein, such as a motor 400, an actuator, and the like for moving components (e.g., optical modules 150) to a desired relative position and/or orientation.

Accordingly, embodiments of the present disclosure provide a head-mountable device with a thermal mitigation system that effectively manages heat while also allowing adjustment of optical modules to accommodate particular users. For a given interpupillary distance to accommodate a user, different heat sinks can be provided with optimized fin patterns, lengths, or shapes. Other mechanisms for managing airflow, such as intake modules, can be provided with custom or adjustable characteristics to achieve different airflow patterns and thereby accommodate movement of the optical modules. Such customization and/or adjustability of thermal mitigations by can allow users to experience optimal performance from temperature-sensitive modules such as displays, cameras, sensors, circuitry, and the like. This can decrease the risk of sensor misalignment with CTE drift, minimize burn-in on displays, and improve overall long-term reliability. Customizing these components by IPD could also mitigate risks of system interferences in drop that may occur at specific IPD positions.

Various examples of aspects of the disclosure are described below as clauses for convenience. These are provided as examples, and do not limit the subject technology.

Clause A: a head-mountable device comprising: a frame; an optical module comprising a display and an optical module engager, the optical module being moveable with respect to the frame; a first heat sink comprising first fins with a first arrangement and a first heat sink engager; a second heat sink comprising second fins with a second arrangement and a second heat sink engager; and a fan mounted to the frame; wherein: in a first assembly of the head-mountable device, the first heat sink is coupled to the optical module by the first heat sink engager and the optical module engager to direct air to the fan while the optical module is in a first position; and in a second assembly of the head-mountable device, the second heat sink is coupled to the optical module by the second heat sink engager and the optical module engager to direct air to the fan while the optical module is in a second position.

Clause B: a head-mountable device comprising: a frame comprising a frame engager; an optical module comprising a display, the optical module being moveable with respect to the frame; a heat sink coupled to the optical module and comprising fins; a first intake module comprising first vanes with a first arrangement and a first intake module engager; a second intake module comprising second vanes with a second arrangement and a second intake module engager; a fan mounted to the frame; and wherein: in a first assembly of the head-mountable device, the first intake module is coupled to the frame by the first intake module engager and the frame engager to direct air to the heat sink while the optical module is in a first position; and in a second assembly of the head-mountable device, the second intake module is coupled to the frame by the second intake module engager and the frame engager to direct air to the heat sink while the optical module is in a second position.

Clause C: a head-mountable device comprising: a frame; an optical module comprising a display, the optical module being moveable with respect to the frame; a heat sink coupled to the optical module and comprising fins; and an intake module slidably coupled to the frame and comprising vanes configured to direct air to the heat sink.

One or more of the above clauses can include one or more of the features described below. It is noted that any of the following clauses may be combined in any combination with each other, and placed into a respective independent clause, e.g., clause A, B, or C.

Clause 1: a pair of the first fins extend to form a first angle; and a pair of the second fins extend to form a second angle, different than the first angle.

Clause 2: a number of the second fins is greater than a number of the first fins.

Clause 3: the first fins extend from the optical module to a first maximum height; and at least some of the second fins extend from the optical module to a second maximum height, less than the first maximum height.

Clause 4: each of the optical module engager, the first heat sink engager, and the second heat sink engager comprise a magnet.

Clause 5: a sensor configured to detect a feature of an eye of a user; and a processor configured to operate a motor to move the optical module based on the feature detected by the sensor.

Clause 6: the optical module is a first optical module; the display is a first display; the optical module engager is a first optical module engager; the head-mountable device further comprises: a second optical module comprising a second display and a second optical module engager, the second optical module being moveable with respect to the frame; a third heat sink comprising third fins with a third arrangement and a third heat sink engager; and a fourth heat sink comprising fourth fins with a fourth arrangement and a fourth heat sink engager; in the first assembly of the head-mountable device, the third heat sink is coupled to the second optical module by the third heat sink engager and the second optical module engager to direct air to the fan while the second optical module is in a third position; and in the second assembly of the head-mountable device, the fourth heat sink is coupled to the second optical module by the fourth heat sink engager and the second optical module engager to direct air to the fan while the second optical module is in a fourth position.

Clause 7: the first optical module and the second optical module are moveable to maintain a substantially equal distance between the first optical module and the fan and between the second optical module and the fan.

Clause 8: a pair of the first vanes extend to form a first angle; and a pair of the second vanes extend to form a second angle, different than the first angle.

Clause 9: each of the frame engager, the first intake module engager, and the second intake module engager comprise a magnet.

Clause 10: the frame engager is a first frame engager; the optical module is a first optical module; the display is a first display; the heat sink is a first heat sink; the fins are first fins; the frame further comprises a second frame engager; the head-mountable device further comprises: a second optical module comprising a second display, the second optical module being moveable with respect to the frame; a second heat sink coupled to the second optical module and comprising second fins; a third intake module comprising third vanes with a third arrangement and a third intake module engager; and a fourth intake module comprising fourth vanes with a fourth arrangement and a fourth intake module engager; in the first assembly of the head-mountable device, the third intake module is coupled to the frame by the third intake module engager and the second frame engager to direct air to the fan while the second optical module is in a third position; and in the second assembly of the head-mountable device, the fourth intake module is coupled to the frame by the fourth intake module engager and the second frame engager to direct air to the fan while the second optical module is in a fourth position.

Clause 11: a fan mounted to the frame and configured to draw air through the intake module and across the heat sink.

Clause 12: the optical module is a first optical module; the display is a first display; the heat sink is a first heat sink; the fins are first fins; the vanes are first vanes; and the head-mountable device further comprises: a second optical module comprising a second display, the second optical module being moveable with respect to the frame; a second heat sink coupled to the second optical module and comprising second fins; and a second intake module slidably coupled to the frame and comprising second vanes configured to direct air to the second heat sink.

Clause 13: a sensor configured to detect a feature of an eye of a user; and a processor configured to operate a motor to move the intake module based on the feature detected by the sensor.

Clause 14: the second fins are arranged in rows with adjacent pairs of the second fins being separated from each other by gaps

As described above, one aspect of the present technology may include the gathering and use of data available from various sources. The present disclosure contemplates that in some instances, this gathered data may include personal information data that uniquely identifies or can be used to contact or locate a specific person. Such personal information data can include demographic data, location-based data, telephone numbers, email addresses, twitter ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, and systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. A head-mountable device comprising:
a frame;
an optical module comprising a display and an optical module engager, the optical module being moveable with respect to the frame;
a first heat sink comprising first fins with a first arrangement and a first heat sink engager;
a second heat sink comprising second fins with a second arrangement and a second heat sink engager; and
a fan mounted to the frame;
wherein:
in a first assembly of the head-mountable device, the first heat sink is coupled to the optical module by the first heat sink engager and the optical module engager to direct air to the fan while the optical module is in a first position; and
in a second assembly of the head-mountable device, the second heat sink is coupled to the optical module by the second heat sink engager and the optical module engager to direct air to the fan while the optical module is in a second position.

2. The head-mountable device of claim 1, wherein:
a pair of the first fins extend to form a first angle; and
a pair of the second fins extend to form a second angle, different than the first angle.

3. The head-mountable device of claim 1, wherein a number of the second fins is greater than a number of the first fins.

4. The head-mountable device of claim 1, wherein the second fins are arranged in rows with adjacent pairs of the second fins being separated from each other by gaps.

5. The head-mountable device of claim 1, wherein:
the first fins extend from the optical module to a first maximum height; and
at least some of the second fins extend from the optical module to a second maximum height, less than the first maximum height.

6. The head-mountable device of claim 1, wherein each of the optical module engager, the first heat sink engager, and the second heat sink engager comprise a magnet.

7. The head-mountable device of claim 1, further comprising:
a sensor configured to detect a feature of an eye of a user; and
a processor configured to operate a motor to move the optical module based on the feature detected by the sensor.

8. The head-mountable device of claim 1, wherein:
the optical module is a first optical module;
the display is a first display;
the optical module engager is a first optical module engager;
the head-mountable device further comprises:
a second optical module comprising a second display and a second optical module engager, the second optical module being moveable with respect to the frame;
a third heat sink comprising third fins with a third arrangement and a third heat sink engager; and
a fourth heat sink comprising fourth fins with a fourth arrangement and a fourth heat sink engager;
in the first assembly of the head-mountable device, the third heat sink is coupled to the second optical module by the third heat sink engager and the second optical module engager to direct air to the fan while the second optical module is in a third position; and
in the second assembly of the head-mountable device, the fourth heat sink is coupled to the second optical module by the fourth heat sink engager and the second optical module engager to direct air to the fan while the second optical module is in a fourth position.

9. The head-mountable device of claim 8, wherein the first optical module and the second optical module are moveable to maintain a substantially equal distance between the first optical module and the fan and between the second optical module and the fan.

10. A head-mountable device comprising:
a frame comprising a frame engager;
an optical module comprising a display, the optical module being moveable with respect to the frame;
a heat sink coupled to the optical module and comprising fins;
a first intake module comprising first vanes with a first arrangement and a first intake module engager;
a second intake module comprising second vanes with a second arrangement and a second intake module engager;
a fan mounted to the frame; and
wherein:
in a first assembly of the head-mountable device, the first intake module is coupled to the frame by the first intake module engager and the frame engager to direct air to the heat sink while the optical module is in a first position; and
in a second assembly of the head-mountable device, the second intake module is coupled to the frame by the second intake module engager and the frame engager to direct air to the heat sink while the optical module is in a second position.

11. The head-mountable device of claim 10, wherein:
a pair of the first vanes extend to form a first angle; and
a pair of the second vanes extend to form a second angle, different than the first angle.

12. The head-mountable device of claim 10, wherein each of the frame engager, the first intake module engager, and the second intake module engager comprise a magnet.

13. The head-mountable device of claim 10, further comprising:
a sensor configured to detect a feature of an eye of a user; and
a processor configured to operate a motor to move the optical module based on the feature detected by the sensor.

14. The head-mountable device of claim 10, wherein:
the frame engager is a first frame engager;
the optical module is a first optical module;
the display is a first display;
the heat sink is a first heat sink;
the fins are first fins;
the frame further comprises a second frame engager;
the head-mountable device further comprises:
a second optical module comprising a second display, the second optical module being moveable with respect to the frame;
a second heat sink coupled to the second optical module and comprising second fins;
a third intake module comprising third vanes with a third arrangement and a third intake module engager; and
a fourth intake module comprising fourth vanes with a fourth arrangement and a fourth intake module engager;
in the first assembly of the head-mountable device, the third intake module is coupled to the frame by the third intake module engager and the second frame engager to direct air to the fan while the second optical module is in a third position; and
in the second assembly of the head-mountable device, the fourth intake module is coupled to the frame by the fourth intake module engager and the second frame engager to direct air to the fan while the second optical module is in a fourth position.

15. The head-mountable device of claim 14, wherein the first optical module and the second optical module are moveable to maintain a substantially equal distance between the first optical module and the fan and between the second optical module and the fan.

16. A head-mountable device comprising:
a frame;
an optical module comprising a display, the optical module being moveable with respect to the frame;
a heat sink coupled to the optical module and comprising fins; and
an intake module slidably coupled to the frame and comprising vanes configured to direct air to the heat sink.

17. The head-mountable device of claim 16, further comprising a fan mounted to the frame and configured to draw air through the intake module and across the heat sink.

18. The head-mountable device of claim 16, further comprising:
a sensor configured to detect a feature of an eye of a user; and
a processor configured to, based on the feature detected by the sensor, operate a motor to move the optical module and slide the intake module.

19. The head-mountable device of claim 16, wherein:
the optical module is a first optical module;
the display is a first display;
the heat sink is a first heat sink;
the fins are first fins;
the vanes are first vanes; and
the head-mountable device further comprises:
a second optical module comprising a second display, the second optical module being moveable with respect to the frame;
a second heat sink coupled to the second optical module and comprising second fins; and
a second intake module slidably coupled to the frame and comprising second vanes configured to direct air to the second heat sink.

20. The head-mountable device of claim 19, further comprising a fan mounted to the frame, wherein the first optical module and the second optical module are moveable to maintain a substantially equal distance between the first optical module and the fan and between the second optical module and the fan.
